(19) United States
(12) Patent Application Publication
(10) Pub. No.: US 2007/0177365 A1
(43) Pub. Date: Aug. 2, 2007

(54) Communications Panel Assemblies and Methods for Mounting the Same

(75) Inventors: Scott Martin Keith, Plano, TX (US); Golam Mabud Choudhury, Warren, NJ (US); Gus Arthur Checketts, Elkhorn, NE (US); Chin Choi-Feng, Dallas, TX (US); Theodore Alan Conorich, Lake Hiawatha, NJ (US); Tim Cronin, Austin, TX (US); John Lapetina, San Francisco, CA (US); Roy Riccomini, Saratoga, CA (US); Andy Logan, Redwood City, CA (US); Cormac Eubanks, San Francisco, CA (US); Mike Krynock, Sunnyvale, CA (US)

Correspondence Address: MYERS BIGEL SIBLEY & SAJOVEC, PO BOX 37428, RALEIGH, NC, 27627, US

(73) Assignee: CommScope, Inc. of North Carolina

(21) Appl. No.: 11/668,859

(22) Filed: Jan. 30, 2007

Related U.S. Application Data
(60) Provisional application No. 60/763,875, filed on Jan. 31, 2006.

(51) Int. Cl. H05K 7/00

(52) U.S. Cl. 361/760

(57) ABSTRACT

A communications panel assembly for use with a mounting surface to manage communications cables and/or connections includes a back panel and a level orientation indicator device. The back panel is configured to be mounted on the mount surface. The level orientation indicator device is integrally mounted on the back panel to indicate an orientation of the back panel. According to some embodiments, the level orientation indicator includes a bubble level device.

### RELATED APPLICATION(S)

The present application claims the benefit of priority from U.S. Provisional Patent Application Ser. No. 60/763,875, filed Jan. 31, 2006, the disclosure of which is incorporated herein by reference in its entirety.

### FIELD OF THE INVENTION

The present invention relates to communications devices and methods and, more particularly, to communications panel assemblies and methods for managing communications cables and/or connections.

### BACKGROUND OF THE INVENTION

Communications panel assemblies such as terminal block panels and spacer brackets are commonly employed to manage communications cables and connections. Terminal block panels (which may also be referred to as patch panels, back panels, or cross-connects) are hardware devices used in the communication equipment industry to connect cables to terminal equipment contained within an environment (e.g., office suites, apartment buildings, etc.). The panels are typically available to accommodate 900 wire pair and 300 wire pair configurations and are often mounted to a wall situated within a closet in the equipment environment. Exemplary panels contain a securing surface that is affixed or fastened to the wall, and a mounting surface configured into a plurality of tangs upon which connecting devices such as connecting blocks are secured. The connecting blocks interface with data carrying cables, such as exterior cables that route data to and from the environment, to cables connected to, for example, terminal devices.

### SUMMARY OF THE INVENTION

According to embodiments of the present invention, a communications panel assembly for use with a mounting surface to manage communications cables and/or connections includes a back panel and a level orientation indicator device. The back panel is configured to be mounted on the mount surface. The level orientation indicator device is integrally mounted on the back panel to indicate an orientation of the back panel. According to some embodiments, the level orientation indicator includes a bubble level device.

According to method embodiments of the present invention, a method for mounting a communications panel assembly on a mounting surface to manage communications cables and/or connections includes: providing a communications panel assembly including a back panel and a level orientation indicator device integrally mounted on the back panel to indicate an orientation of the back panel; positioning the back panel adjacent the mount surface; orienting the back panel using the level orientation indicator device to level the back panel on the mount surface; and securing the back panel to the mount surface. According to some embodiments, the level orientation indicator includes a bubble level device.

Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

FIG. 1 is a front perspective view of a terminal block panel assembly according to embodiments of the present invention mounted on a wall.

FIG. 2 is a rear perspective view of the terminal block panel assembly of FIG. 1.

FIG. 3 is an exploded, rear perspective view of the terminal block panel assembly of FIG. 1.

FIG. 4 is an enlarged, rear perspective view of a level indicator assembly forming a part of the terminal block panel assembly of FIG. 1.

FIG. 5 is a front perspective view of a spacer bracket assembly according to further embodiments of the present invention.

FIG. 6 is an exploded, front perspective view of the spacer bracket assembly of FIG. 5.

### DETAILED DESCRIPTION OF EMBODIMENTS OF THE INVENTION

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein the expression “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

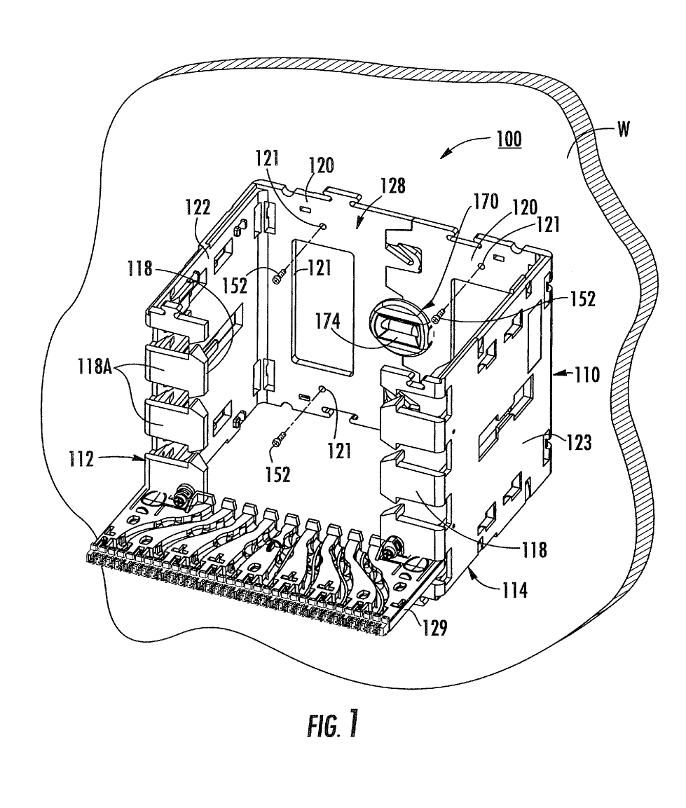

Turning now to the drawings, a terminal block panel assembly or patch panel assembly 100 in accordance with embodiments of the present invention is shown in FIGS. 1-4. The panel assembly 100 may as a matter of design choice be manufactured as a 900 pair device, a 300 pair device, a 100 pair device, or any other configuration as is known in the art. The panel assembly 100 includes a back panel 110 and a level indicator assembly 170, as discussed in more detail below.

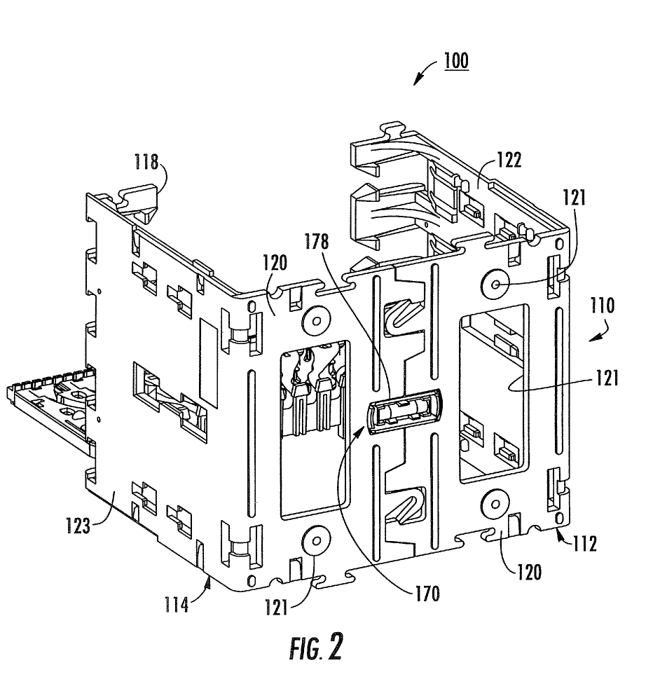

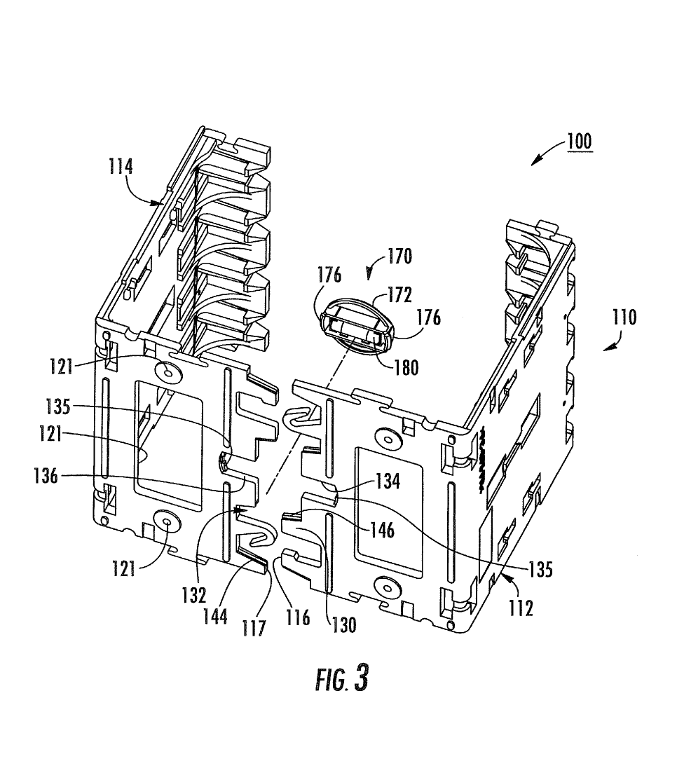

The back panel 110 is C-shaped and includes a first panel member 112 and a second panel member 114 that may be manufactured, such as by molding, from an electrically non-conductive material such as a foamed plastic or polymeric material. When attached together, the panel members 112, 114 form the back panel 110. The second panel member 114 may be identical to the panel member 112 and is shown oriented 180 degrees with respect to the panel member 112. Each panel member 112, 114 has a crenelated engaging edge 116, 117 (FIG. 3) defining a series of interlocking structures 130, 132 and a level indicator mount opening 178 (FIG. 2).

Each panel further has a mounting edge 118 defining a series of mounting structures 118A. According to some embodiments and as shown, the mounting structures are configured as a plurality of tangs, which may be spaced equidistant from each other. Each tang can have a mounting hole or other securing feature to facilitate mounting thereto of interface devices, such as connection blocks 129. In a typical application, a single connection block may be mounted across two opposing tangs 118A so that a first end of the connection block is mounted to a tang 118A on the first panel member 112 and a second end of the connection block is mounted to a tang 118A on the second panel member 114.

The engaging edges 116, 117 and the mounting structures 118A for each panel member 112, 114 are connected to a rear or securing wall 120. Each panel member 112, 114 has a side wall 122, 123 which offsets each mounting edge 118 from its respective securing wall 120.

When the first panel member 112 and the second panel member 114 are connected together, a trough 128 is formed which is bounded between the side walls 122, 123, the securing walls 120 and the mounting edges 118. The trough 128 is provided to house, contain or receive a plurality of communication cables (not shown), some of which simply extend through and along the trough 128 while others are connected to devices such as connection blocks 129 that are mounted to mounting structures 118A. Cable management structures such as loop members may be secured to the panel members 112, 114 to hold or guide the cables in the trough 128.

Each securing wall 120 has one or more cut-outs or fastener holes 121 or other features for releasably mounting each panel member 112, 114 to a hook or fastener, such as a screw secured to or mounted on a wall or backboard. Other securing devices such as nails, clips, etc. may be used for securing the first and second panel members 112, 114 to a wall or other structure.

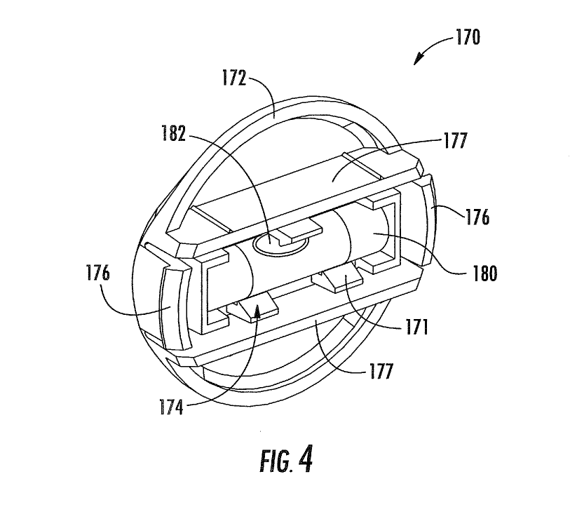

The level indicator assembly 170 is shown enlarged in FIG. 4. The assembly 170 includes a body or housing 172 and a level orientation indicator (hereinafter, “level indicator”) device 180.

The body 172 has an opening 174 defined therein. Mechanical securing features such as latch tabs 176 are formed on opposed sides of the housing 172. Locator walls 177 are also formed on the body 172. Holding tabs 171 are formed on the body 172 adjacent the opening 174. The body 172 may be formed of any suitable material. According to some embodiments, the body 172 is formed of a polymeric material such as a foamed plastic.

The level indicator device 180 is mounted in the opening 174. The level indicator device 180 may be secured in the body 172 in any suitable manner, for example, by adhesive, mechanical interlock, and/or molding. In the illustrated embodiment, the device 180 is retained in the opening 174 by the holding tabs 171.

According to some embodiments and as shown, the level indicator device 180 is a bubble level. The bubble level 180 is configured to indicate when the bubble level 180 is horizontally oriented. For example, the bubble level 180 may include a translucent tube containing a liquid and a bubble 182. The bubble level 180 indicates a horizontally level position when the bubble 182 is centered relative to indicia on the tube or elsewhere.

With reference now to FIG. 3, the crenellated engaging edges 116, 117 contain alternating protrusions 130 and recesses 132 that interlock, in tongue-in-groove manner, with each other when the first panel member 112 and the second panel member 114 are brought into close proximity. In other words, the protrusions 130 on the engaging edge 116 of the first member 112 seat within corresponding recesses 132 formed in the engaging edge 117 of the second member 114. Likewise, protrusions 130 formed on the engaging edge 117 seat within corresponding recesses 132 formed in the engaging edge 116. According to some embodiments and as shown, each protrusion 130 and recess 132 contains a pair of angled sides joined by a straight side. For each protrusion and recess, a channel/groove 144 is formed in one of the angled sides of each pair and a rail 146 is formed on the other angled side of each pair. When the engaging edges 116 and 117 are brought into contact with each other, the rails 146 slide and seat within the channels 144 in a substantial tongue-in-groove arrangement. Other configurations may be employed. For example, each protrusion may have only rails, while each recess may define a groove on both angled sides.

To ensure that the first member 112 and second member 114 remain secured to each other so that the trough 128 will maintain containment of cables extending therethrough, the alternating protrusions 130 and recesses 132 are configured to maintain engagement between the first member 112 and second member 114 and a fastening feature may be provided for locking the two members 112, 114 together.

Additionally, when the panel members 112, 114 are joined as described, the mounting recesses 134, 136 together define a level device mount slot or opening 178 (FIG. 2). The level indicator assembly 170 is mounted in the opening 178. One or more locator features may be provided on the panel members 112, 114 and/or the level indicator assembly 170 (e.g., the body 172) to ensure or facilitate proper orientation of the level indicator assembly 170 with respect to the back panel 110. In the illustrated embodiment, the opening 178 is asymmetric to mate with the locator walls 177 to ensure that the assembly 170 is properly oriented in the back panel 110. The housing 172 is received in the opening 178 such that the tabs 176 interlock with respective tabs 135 (FIG. 3) on the edges 116, 117 in the recesses 134, 136 to hold the level indicator assembly 170 in place. Adhesive and/or other mechanical coupling features may be employed as well.

The panel members 112, 114 may be engaged to form the back panel 100 as described, and the level indicator assembly 170 can thereafter be inserted or snapped into the opening 178. Alternatively, the assembly 100 may be assembled by positioning the level indicator assembly 170 between the panel members 112, 114 and bringing the edges 116, 117 into interlocking engagement with each other and the level indicator assembly 170 as described above.

In a typical application, the back panel 110 is mounted in an equipment closet or other structure and provides an interface between devices contained in an environment and devices contained outside the environment. The interface is completed by way of cables passing through the back panel 110 to interface devices mounted to the mounting structures 118A of the first and second panel members 112, 114, such as by connecting the cables to, for example, connection blocks 129 or other interfacing devices mounted to the mounting surfaces.

The back panel 110 may be mounted on the support wall using any suitable securing device. For example, screws (e.g., drywall screws) may be mounted in the support wall and the back panel 110 can thereafter be hung on the screws with the heads of the screws inserted through the fastener holes 121. Similarly, hooks (individual or mounted on a shared hanger rod or the like) may be mounted on the support wall and the back panel 110 can thereafter be hung on the hooks with the hooks inserted through the fastener holes 121. Suitable clips may be used in place of or in addition to screws or hooks. As a further alternative, the back panel 110 can be positioned on the wall and screws or the like can be driven through the walls 120 and into the support wall. In this case, the screws may be driven through the holes 121 and or through the material of the walls 120.

When mounting the back panel 110, it may be necessary or desirable to properly level the back panel 110. Conventionally, this may be accomplished by using a separate leveling tool (e.g., a beam fitted with a bubble level), which is placed on the back panel as the wall is marked for screw placement or the fasteners are driven through the back panel. Alternatively, a separate level tool may be used to position a hanger rod, which is thereafter secured to the support wall for hanging the back panel. These methods thus present the need for a separate level tool and special handling of the level tool, which may be cumbersome and/or time consuming.

In accordance with method embodiments of the present invention, the foregoing problems can be obviated by the provision of the level indicator assembly 170 integral with the back panel 110. The installer need only position the assembly 100 on the support wall and adjust the position until the level indicator device 180 indicates a horizontally level position. The installer can then insert the fasteners through the back panel 110 and into the support wall. Alternatively, the installer can then mark the support wall for mounting a hanging rod or the like, for example, using the back panel 110 as a template.

By way of illustration, FIG. 1 shows the assembly 100 positioned on a support wall W and leveled using the level indicator device 180 in preparation for insertion of screws 152 through the openings 121.

Because the level indicator device 180 is mounted on the rear walls 120, it need not affect the appearance of the assembly 100 in service.

The level indicator device 180 may be mounted elsewhere on the back panel 110. For example, the level indicator device 180 may be mounted on one of the mounting structures 118A or a similar structure.

The level indicator assembly 170 may be mounted on the back panel 110 in ways other than those discussed above. For example, the level indicator assembly 170 may be insert molded into the back panel 110 or mounted on a surface of the back panel 110 (e.g., using adhesive, one or more fasteners, a mechanical structure integral to the level indicator assembly 170 or the back panel 110, etc.). The bubble level 180 or other level indicator device may be mounted on the back panel 110 without the body 172. For example, the bubble level 180 can be secured to the back panel 110 by adhesive, molding, a fastener, and/or a mechanical structure integral to the level indicator device 180 or the back panel 110.

Other types of level indicator devices may be used in addition to or in place of the bubble level 180.

While a two-piece back panel 110 is shown and described, back panels of other designs may be employed as well. For example, the back panel may be of a one piece construction. Further aspects and alternatives for the construction and use of back panels according to some embodiments of the present invention will be appreciated from the disclosure of U.S. Pat. No. 6,106,329 to Baker, III et al., the disclosure of which is incorporated herein by reference in its entirety.

In accordance with further embodiments of the invention, a level indicator assembly as described herein may be incorporated into a cable management spacer bracket of the type mounted in a space between two adjacent, side-by-side, spaced apart back panels, and used in the manner described herein to mount the spacer bracket on a support surface.

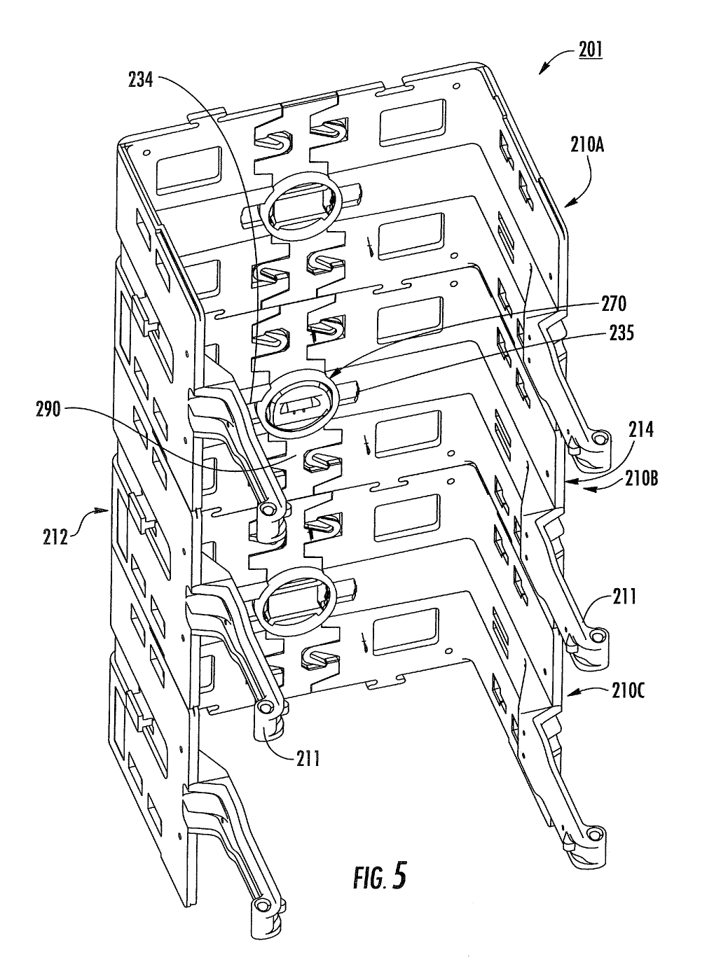

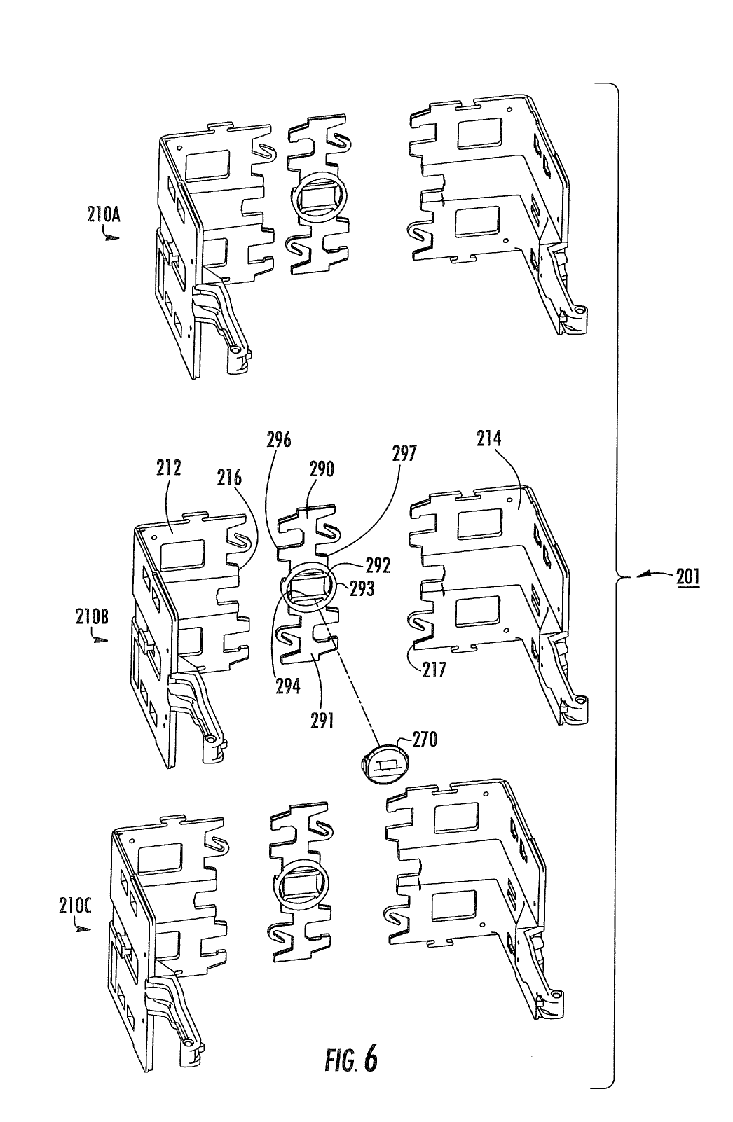

With reference to FIGS. 5 and 6, a spacer bracket assembly 201 according to embodiments of the present invention is shown therein. The spacer bracket assembly 201 includes three interconnected back panels 210A, 210B, 210C. The back panels 210A, 210B, 210C as illustrated are identical to each other except that the assembly 210B further includes a level indicator assembly 270 corresponding to the level indicator assembly 170. Accordingly, only the back panel 210B will be described hereinafter, it being appreciated that this description likewise applies to the back panels 210A, 210C.

The back panel 210B includes panel members 212, 214 generally corresponding to the panel members 112, 114 except that the front edges thereof are provided with posts 211 in place of connection block mounting tabs. The panel members 212, 214 may be mated directly edge to edge as described above with regard to the panel members 112, 114 to form a back panel. In this case, the level indicator assembly 270 may be mounted in an opening or slot collectively defined by recesses 234, 236 as described above with regard to the opening 178 and the recesses 134, 136. However, according to some embodiments and as illustrated, a coupling member or expansion strip 290 may be inserted between the engaging edges 216, 217 of the panel members 212, 214 and coupled along its opposed engaging edges 296, 297 with the engaging edges 216, 217, respectively. In this manner, a widthwise expanded back panel 210B can be formed. For example, the back panel may be 8.5 inches wide without a coupling member, 10 inches wide with the coupling member 290, and 12 inches wide with a coupling member of a second, greater width.

The coupling member 290 includes a body 291 and a level indicator mount portion 292. The mount portion 292 includes an opening 294 corresponding to the opening 178 and a bordering ring structure 293. The mount portion 292 may include additional features such as securing tabs corresponding to the tabs 135.

The level indicator assembly 270 is mounted in the opening 294. The level indicator assembly 270 can thereby be employed in the same manner as discussed above to orient and install the spacer bracket assembly 201 on a mount surface or wall.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

What is claimed is:

1. A communications panel assembly for use with a mounting surface to manage communications cables and/or connections, the communications panel assembly comprising:
a back panel configured to be mounted on the mount surface; and
a level orientation indicator device integrally mounted on the back panel to indicate an orientation of the back panel.

2. The communications panel assembly of claim 1 wherein the level orientation indicator device includes a bubble level device.

3. The communications panel assembly of claim 1 wherein:
the back panel includes first and second panel members each having a side wall and an engaging edge and being coupled to one another along their respective engaging edges to define a trough extending between the side walls of the first and second panel members; and
the level orientation indicator device is mounted on the first and second panel members between the engaging edges thereof.

4. The communications panel assembly of claim 1 wherein:
the back panel includes first and second panel members and a coupling member, the first and second panel members having first and second engaging edges, respectively, and each having a respective side wall, the coupling member having opposed third and fourth engaging edges, the first and second engaging edges being coupled to the third and fourth engaging edges, respectively, to define a trough extending between the side walls of the first and second panel members; and
the level orientation indicator device is mounted on the coupling member.

5. The communications panel assembly of claim 1 including an indicator housing, wherein the level orientation indicator device is mounted on the indicator housing.

6. The communications panel assembly of claim 5 wherein at least one of the back panel and the indicator housing includes a mechanical securing feature configured to secure the level orientation indicator device to the back panel.

7. The communications panel assembly of claim 1 wherein the back panel includes at least one mount hole to receive a fastener to mount the communications panel assembly on a wall surface.

8. The communications panel assembly of claim 1 wherein the communications panel assembly is a terminal block panel assembly defining a trough adapted to receive communications cables and including mounting structures configured to support communications connecting blocks.

9. The communications panel assembly of claim 1 wherein the communications panel assembly is a spacer bracket assembly configured to be mounted between a pair of terminal block panel assemblies.

10. The communications panel assembly of claim 1 wherein the back panel defines a trough and including communications cables routed through the trough.

11. A method for mounting a communications panel assembly on a mounting surface to manage communications cables and/or connections, the method comprising:
providing a communications panel assembly including a back panel and a level orientation indicator device integrally mounted on the back panel to indicate an orientation of the back panel;
positioning the back panel adjacent the mount surface;
orienting the back panel using the level orientation indicator device to level the back panel on the mount surface; and
securing the back panel to the mount surface.

12. The method of claim 11 wherein the level orientation indicator device includes a bubble level device.

13. The method of claim 11 wherein the back panel includes first and second panel members each having a side wall and an engaging edge, the method including:
coupling the first and second panel members to one another along their respective engaging edges to define a trough extending between the side walls of the first and second panel members; and
mounting the level orientation indicator device on the first and second panel members between the engaging edges thereof.

14. The method of claim 11 wherein the back panel includes first and second panel members and a coupling member, the first and second panel members having first and second engaging edges, respectively, and each having a respective side wall, the coupling member having opposed third and fourth engaging edges, the method including:
coupling the first and second engaging edges to the third and fourth engaging edges, respectively, to define a trough extending between the side walls of the first and second panel members; and
mounting the level orientation indicator device on the coupling member.

15. The method of claim 11 including an indicator housing, wherein the level orientation indicator device is mounted on the indicator housing.

16. The method of claim 15 including securing the level orientation indicator device to the back panel using at least one mechanical securing feature on at least one of the back panel and the indicator housing.

17. The method of claim 11 wherein securing the back panel to the mount surface includes inserting at least one fastener through at least one mount hole in the back panel and into a wall surface.

18. The method of claim 11 wherein the communications panel assembly is a terminal block panel assembly defining a trough and including mounting structures, the method including installing connecting blocks on the mounting structures and routing communications cables through the trough.

19. The method of claim 11 wherein the communications panel assembly is a spacer bracket assembly, the method including mounting the spacer bracket assembly on the mount surface between a pair of terminal block panel assemblies.
